(19) United States
(12) Patent Application Publication
(10) Pub. No.: US 2023/0317673 A1
(43) Pub. Date: Oct. 5, 2023

(54) FAN OUT FLIP CHIP SEMICONDUCTOR PACKAGE

(71) Applicant: Texas Instruments Incorporated, Dallas, TX (US)

(72) Inventors: Yiqi Tang, Allen, TX (US); Vivek Swaminathan Sridharan, Dallas, TX (US); Rajen Manicon Murugan, Dallas, TX (US); Patrick Francis Thompson, Allen, TX (US)

(21) Appl. No.: 17/710,941

(22) Filed: Mar. 31, 2022

(51) Int. Cl. H01L 23/00; H01L 23/498

(52) U.S. Cl. CPC H01L 24/73; H01L 24/24; H01L 24/16; H01L 24/20; H01L 23/49816; H01L 24/17; H01L 24/19; H01L 2224/73209; H01L 2224/16225; H01L 2224/16245; H01L 2224/24226; H01L 2224/24246; H01L 2924/37001; H01L 2924/186; H01L 2924/182; H01L 2224/2101; H01L 2224/2105; H01L 2224/17134

(57) ABSTRACT

A described example includes: a reconstituted semiconductor device flip chip mounted on a device side surface of a package substrate, the package substrate having terminals for connecting the package substrate to a circuit board, the reconstituted semiconductor device further including: a semiconductor die mounted in a dielectric layer and having bond pads spaced from one another by at least a first pitch distance that is less than 100 microns; a redistribution layer formed over the bond pads having conductors in passivation layers; solder bumps on the redistribution layer coupled to the bond pads of the semiconductor die, the solder bumps spaced from one another by at least a second pitch distance that is greater than the first pitch distance; and solder joints formed between the package substrate and the solder bumps, the solder joints coupling the package substrate to the semiconductor die in the reconstituted semiconductor device.

### TECHNICAL FIELD

This relates generally to packaging electronic devices, and more particularly to assembling flip chip packaged semiconductor devices.

### BACKGROUND

Processes for producing packaged semiconductor devices include mounting the semiconductor devices to a package substrate, and then covering the electronic devices with a mold compound in a molding process to form packages. When semiconductor devices are mounted on package substrates in flip chip packages, a semiconductor die has interconnects that extend from a proximal end placed on bond pads on a device side surface of the semiconductor die to a distal end. In a flip chip package, the semiconductor die is mounted with the device side surface facing a package substrate. The interconnects can include a conductive post connect with a proximate end on the bond pad and distal end facing away from the bond pad, and solder such as a solder ball or solder bump on the distal end of the post connect. In alternatives, the interconnects can include a conductive adhesive, or in another example, a metal to metal bond can be formed between the post connect and a metal land. In an example using solder bumps, when the semiconductor die is flip chip mounted to the package substrate, the solder bumps at the distal end of the post connects are subjected to a thermal reflow process so that the solder melts and flows to form solder joints. The solder joints mechanically attach and electrically couple the semiconductor die to the package substrate. The solder joints attach the conductive post connects to conductive areas on the package substrate. The package substrate provides terminals for the packaged device, for example ball grid array (BGA) balls. The packaged semiconductor device can then be mounted to a circuit board or module for use.

As the size and number of connections increase, and as semiconductor dies decrease in size, the pitch distance measured from center to center among the conductive post connects decreases. For some example dies, the largest pitch that allows all the interconnects to be placed on the die is smaller than the smallest pitch distance available for fabrication or assembly. The pitch requirements for the fabrication and assembly using solder bumps can be due to processing limitations in forming the post connects and solder bumps, including critical dimension requirements due to photolithography limitations, or can be due to minimum pitch limitations in the assembly process. To meet the spacing requirements for the post connect locations on the package substrate, the size of the semiconductor die may be increased to a size greater than the die area needed to fabricate the circuitry on the semiconductor die, so that the bond pads on the semiconductor die are spaced apart enough to provide the needed spacing for the post connect and solder bump processes. Because larger silicon dies reduce the number of dies made on a single wafer, the costs per die substantially increase when die area is increased. A flip chip package assembly that enables the use of smaller silicon dies is needed to increase integration and reduce costs per device.

### SUMMARY

A described example includes: a reconstituted semiconductor device flip chip mounted on a device side surface of a package substrate, the package substrate having terminals for connecting the package substrate to a circuit board. The reconstituted semiconductor device further includes: a semiconductor die mounted in a dielectric layer and having bond pads spaced from one another by at least a first pitch distance of less than 100 microns; a redistribution layer formed over the bond pads having conductors in passivation layers; solder bumps on the redistribution layer coupled to the bond pads of the semiconductor die, the solder bumps spaced from one another by at least a second pitch distance that is greater than the first pitch distance; and solder joints formed between the package substrate and the solder bumps, the solder joints coupling the package substrate to the semiconductor die in the reconstituted semiconductor device.

### BRIEF DESCRIPTION OF THE DRAWINGS

FIGS. 1A-1B are cross-sectional views of a flip chip packaged semiconductor device in a ball grid array (BGA) package.

FIGS. 2A-2B are a projection view and a close up view of a semiconductor wafer including semiconductor dies and an individual semiconductor die from the semiconductor wafer.

FIG. 3A-3H illustrate, in a series of cross-sectional views, selected steps for making reconstituted semiconductor devices for use in an arrangement.

FIGS. 4A-4E illustrate, in a series of cross-sectional views, steps for forming a flip chip semiconductor device package using a reconstituted semiconductor device of the arrangements.

FIG. 5 illustrates, in a flow diagram, a method for making a semiconductor device package using a reconstituted semiconductor device in an arrangement.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor die” is used herein. As used herein, a semiconductor die can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor die can include passive devices such as resistors, inductors, filters, or active devices such as transistors. The semiconductor die can be an integrated circuit with hundreds or thousands of transistors coupled to form a functional circuit, for example a microprocessor or memory device. The semiconductor die can be a passive device such as a sensor, example sensors include photocells, transducers, and charge coupled devices (CCDs), or can be a micro electro-mechanical system (MEMS) device, such as a digital micromirror device (DMD). The semiconductor die includes a semiconductor substrate that has a device side surface and an opposite backside surface. Semiconductor processes form devices on the device side surface of the semiconductor die.

The term “packaged semiconductor device” is used herein. A packaged semiconductor device has at least one semiconductor die electronically coupled to terminals and can have a package body that protects and covers the semiconductor die, although in some device packages the backside of the semiconductor die is exposed. In some arrangements, multiple semiconductor dies can be packaged together. For example, a power metal oxide semiconductor (MOS) field effect transistor (FET) semiconductor die and a logic semiconductor die (such as a gate driver die or controller device die) can be packaged together to from a single packaged electronic device. Additional components such as passives can be included in the packaged electronic device. The semiconductor die is mounted to a package substrate that provides conductive leads, a portion of the conductive leads form the terminals for the packaged electronic device. The semiconductor die can be flip chip mounted with the device side surface facing a package substrate surface, and the semiconductor die mounted to the leads of the package substrate by conductive post connects attached to the package substrate by solder such as solder balls or bumps. The packaged electronic device can have a package body formed by a thermoset epoxy resin in a molding process, or by the use of epoxy, plastics, resins that are liquid at room temperature and are subsequently cured, or by use of a laminated film. The package body could be formed using an additive manufacturing process with sequential material deposition or a drop on demand process. The package body may provide a hermetic package for the packaged electronic device. The package body may be formed in a mold using an encapsulation process, however, a portion of the leads of the package substrate are not covered during encapsulation, these exposed lead portions provide the exposed terminals for the packaged electronic device.

The term “package substrate” is used herein. A package substrate is a substrate arranged to receive a semiconductor die and to support the semiconductor die in a completed semiconductor package. Package substrates can include conductive lead frames, which can be formed from copper, aluminum, stainless steel and alloys such as Alloy 42 and copper alloys. For flip chip packages, a portion of the leads are arranged to receive solder joints between the leads and the conductive post connects for the semiconductor die. The solder joints form the physical die attach and the electrical connection to the package substrate. When lead frames are used as package substrates, the lead frames can be provided in strips or arrays. Dies can be placed on the strips or arrays, the dies flip chip mounted to the lead frames and the lead frames and dies then covered with mold compound in a molding process.

Alternative package substrates include pre-molded lead frames (PMLF) and molded interconnect substrates (MIS) for receiving semiconductor dies. Routable lead frames, which include multiple levels of conductors in dielectric material, can be used. These package substrates can include dielectrics such as liquid crystal polymer (LCP) or mold compound, and can include one or more layers of conductive portions in the dielectrics. Repeated plating and patterning can form multiple layers of conductors spaced by dielectrics, and conductive vias connecting the conductor layers through the dielectrics, the dielectrics can be mold compound. The package substrates can include lead frames, and can include plated, stamped and partially etched lead frames. In a partially etched lead frame, two levels of metal can be formed by etching a pattern from one side of a metal substrate configured for lead frames, and then etching from the other side, to form full thickness and partial thickness portions, and in some areas, all of the metal can be etched through to form openings through the partial etch lead frames. The package substrate can also be tape-based and film-based, and these can form substrates carrying conductors. Ceramic substrates, laminate substrates with multiple layers of conductors and insulator layers; and printed circuit board substrates of ceramic, fiberglass or resin, or glass reinforced epoxy substrates such as flame retardant 4 (FR4) can be used as the package substrates.

The term “post connect” is used herein. As used herein, a post connect is a structure made of a conductive material, for example copper or copper alloys, gold or gold alloys, or combinations of conductive metal that provides a connection between a semiconductor die and a package substrate. A proximal end of the post connects is mounted to a bond pad on the device side surface of a semiconductor die, while a distal end of the post connect is extended away from the bond pad of the semiconductor die. When the packaged semiconductor device is oriented with the semiconductor die positioned over and facing a die mount surface of a package substrate in a flip chip orientation, the post connect makes a vertical connection between a conductive portion of the package substrate and the bond pad of the semiconductor die. Some references describe a type of post connect as a “controlled collapse chip connection” or as “C4” bumps. The conductive post connect includes a post of conductor material and has a distal end facing away from the surface of the bond pad on the semiconductor die, where a proximal end of the post connect is mounted to the bond pad.

A package substrate, such as a lead frame, molded interconnect substrate (MIS), premolded lead frame (PMLF) or multilayer package substrate, has conductive portions on a planar die side surface. Leads of a metal lead frame are conductive all along the surfaces, while for other substrate types, conductive lands in dielectric substrate material are arranged and aligned to electrically and mechanically connect to the conductive post connects. The post connects can extend along the same direction as a conductive lead in the package substrate, so that the post connect appears as a rail or has a rectangular cross section. When the post connect is copper and is pillar shaped and has solder bumped at the end, it may be referred to as a “copper pillar bump.” A copper pillar bump or copper bump is therefore an example of a post connect. In addition to the pillar shape, the post connect can also be a column, rectangle or rail shape, and can have an oval, round, square or rectangular cross section. In examples, multiple post connects can be arranged in parallel to one another with additional post connects coupled to a common trace on a package substrate, to provide a low resistance path between the semiconductor die and the package substrate. A thermal reflow process is used to melt solder between the post connect and the package substrate to make a solder joint. The solder joint provides both a mechanical attachment and an electrical connection between the semiconductor die and the package substrate. Post connects are used to form several, tens, hundreds or thousands of connections between a semiconductor die and a package substrate in fine pitch semiconductor packages. As device sizes continue to fall and the density of connections rises, these sizes may decrease. Spacing between post connects may also decrease.

In packaging semiconductor devices, a mold compound may be used to partially cover a package substrate, to cover a semiconductor die, and to cover the connections from the semiconductor die to the package substrate. This “encapsulation” process is often an injection molding process, where thermoset mold compound such as epoxy resin can be used. A room temperature solid or powder mold compound can be heated to a liquid state and then molding can be performed. Transfer molding can be used. Unit molds shaped to surround an individual device may be used, or block molding may be used, to form the packages simultaneously for several devices using molten mold compound. The devices can be provided in an array of several, hundreds or even thousands of devices in rows and columns that are molded together. After the molding, the individual packaged devices are cut from each other in a sawing operation by cutting through the mold compound and package substrate in saw streets formed between the devices. Portions of the package substrate leads are exposed from the mold compound package to form terminals for the packaged semiconductor device.

In flip chip die attach processes, solder balls, solder columns, or solder bumps are used to form solder joints between the conductive post connects and a conductive lead or land on a package substrate. The post connects are formed extending from bond pads of the semiconductor die. The semiconductor die is then oriented with the distal ends of the post connects facing a die mounting surface of a circuit board or package substrate. A solder reflow process is used to attach the post connects to conductive die pads or leads on the package substrate, the solder joints forming a physical attachment and an electrical connection between the package substrate and the semiconductor die.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing including packaging. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser or other cutting tool to pass between the molded electronic devices to separate the devices from one another. This process is another form of singulation. When the molded electronic devices are provided in a strip with one device adjacent another device along the strip, the saw streets are parallel and normal to the length of the strip. When the molded electronic devices are provided in an array of devices in rows and columns, the saw streets include two groups of parallel saw streets, the two groups are normal to each other and so the saw will traverse the molded electronic devices in two different directions to cut apart the packaged electronic devices from one another in the array.

The term “quad flat no-lead” or “QFN” is used herein for a type of electronic device package. A QFN package has conductive leads that are coextensive with the sides of a molded package body and the leads are on four sides. Alternative flat no-lead packages may have leads on two sides or only on one side. These can be referred to as “small outline no-lead” or “SON” packages. No lead packaged electronic devices can be surface mounted to a board. Leaded packages can be used with the arrangements where the leads extend away from the package body and are shaped to form a portion for soldering to a board. A dual in line package, or DIP, can be used with the arrangements. A small outline package or SOP can be used with the arrangements.

The term “ball grid array” or “BGA” is used herein for another type of semiconductor device package. A BGA package has solder balls on a board side surface, which form the terminals of the semiconductor device package. The BGA package can be mounted to a printed circuit board by a solder reflow process to form solder joints between the BGA package and the printed circuit board. For a semiconductor device with many input and output terminals, the BGA package can have solder balls in a grid or array on the board side of the semiconductor device package.

The term “reconstituted semiconductor device” is used herein. A reconstituted semiconductor device includes a semiconductor die that is partially covered in a dielectric material, with a redistribution layer formed over the semiconductor die. In an example arrangement, the semiconductor die has bond pads at a first pitch distance, and the redistribution layer had conductors in passivation layers that couple the bond pads to conductive lands configured for a solder ball or post connect, the solder balls or post connects are at a second pitch that is larger than the first pitch distance.

In the arrangements, a semiconductor die has post connects mounted with a proximate end on bond pads on a device side surface of the semiconductor die, and having solder balls or bumps formed on a distal end of the post connects. Semiconductor dies are singulated from a semiconductor wafer. The semiconductor dies have bond pads on a device side surface with a first minimum pitch distance between the bond pads. The semiconductor dies are placed on a carrier spaced from one another. A dielectric such as a mold compound, thermoplastic, resin or epoxy is formed over a portion of the semiconductor dies to form a reconstituted wafer with the semiconductor dies having bond pads exposed from the dielectric. A redistribution layer is formed over the bond pads of the semiconductor dies, bumps or post connects are formed on the redistribution layer to form solder balls or solder bumps with a second pitch distance between them, the second pitch distance being greater than the first pitch distance. The reconstituted wafer is then singulated to form a reconstituted semiconductor device that includes the semiconductor dies and the redistribution layers with the solder bumps. The reconstituted semiconductor device is then flip chip mounted to a package substrate using a solder reflow process. The package substrate can be a ceramic circuit board, a printed circuit board of fiberglass, such as flame retardant 4 (FR4) or other dielectric, a pre-molded lead frame, a multilayer package substrate formed by additive manufacturing using plating of conductors and dielectric in layers, or another package substrate. In an example arrangement, the package substrate is a ball grid array (BGA) package substrate and has solder balls on a surface opposite a device side surface. A protective lid or a molding process can provide a protective package body to complete the packaged device. Use of the reconstituted semiconductor device with the second pitch between the bumps or solder balls enables a semiconductor die with the first smaller pitch between bond pads to be flip chip mounted in a semiconductor device package, enabling the use of smaller semiconductor dies. Use of smaller semiconductor dies, such as are increasingly produced in advanced semiconductor processes, along with the use of flip chip BGA packages, allows for reduced costs per device.

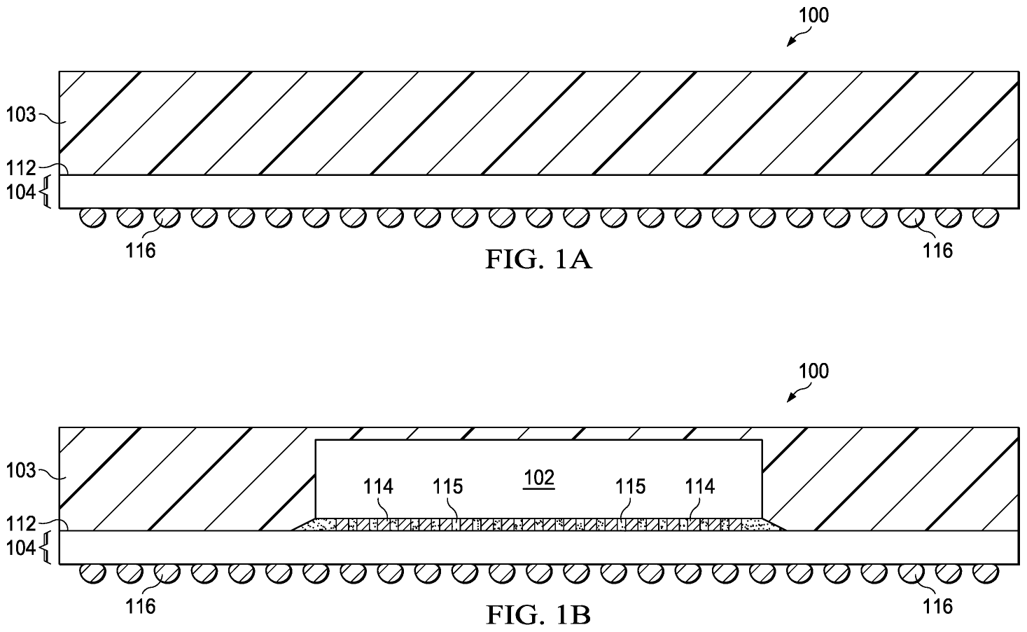

FIG. 1A illustrates, in a cross sectional view, a semiconductor device package 100, which is a BGA package. The semiconductor device package 100 has a body 103 formed from a dielectric such as a thermoset mold compound, for example epoxy resin mold compound. Other dielectric materials, such as resins, epoxies, or plastics can be used. The epoxy resin mold compound can include fillers to increase thermal conductivity. BGA balls 116 are part of a package substrate 104 that supports a semiconductor die (not visible in FIG. 1, as it is obscured by the package body 103, see FIG. 1B) within the semiconductor device package 100, the BGA balls 116 are exposed from the package body 103 and form electrical terminals for the semiconductor device package 100. The semiconductor device package 100 can be mounted to a circuit board using surface mount technology (SMT) using solder balls 116 to form solder joints. Package sizes for semiconductor devices are continually decreasing, and currently can be several millimeters on a side to less than one millimeter on a side, although larger and smaller sizes are also used. Future package sizes may be smaller. The number of terminals 116 is increasing with additional integration of circuitry on some semiconductor dies as entire systems are formed on a single semiconductor die.

FIG. 1B illustrates in an another cross sectional view the BGA package 100 of FIG. 1A with the dielectric forming package body 103 of the package 100 shown in a transparent form. Semiconductor die 102 is flip chip mounted to a device side surface 112 of the package substrate 104 by solder bumps 114. An underfill 115, which can be an epoxy, resin or polymer, is shown protecting the solder joints between the solder bumps 114 and the package substrate 104. In an alternative, the underfill 115 can be omitted and the material forming package body 103, which can be a mold compound, can extend to the area beneath the semiconductor die 102. The semiconductor die 102 can be connected by solder balls formed on the bond pads, or by post connects with solder bumps formed on the post connects, such as copper pillar bumps.

As semiconductor processes continue to advance, the minimum feature sizes that can be manufactured on a semiconductor die continue to fall. The semiconductor die sizes fall with the process node minimum feature size. Smaller semiconductor dies tend to reduce device costs, as the number of semiconductor devices produced on a single wafer increases, while the processing costs per wafer remains relatively stable, so that as the minimum feature sizes falls, and die sizes shrink, the number of dies produced per wafer increases, and the costs per completed device fall. As the semiconductor dies become smaller, the pitch between bond pads on the device side surface of the semiconductor dies also falls, in a particular example, to a bond pad pitch of less than about 60 microns. However, the processes used to form solder balls or bumps are not impacted by the semiconductor process node minimum feature size, and these processes have larger minimum pitch requirements, such as 150 microns center to center. When a semiconductor die is flip chip mounted, as is in FIG. 1B, the minimum bond pad pitch that can be used can be limited by solder bump process rules, which means that the semiconductor dies cannot be produced with the minimum die sizes for the flip chip packages. One approach to solve this issue is to make the semiconductor dies larger in area with correspondingly larger bond pad pitch distances, to meet the solder bump process requirements, however this approach greatly reduces the device yield per wafer and increases semiconductor die costs.

In the arrangements, a reconstituted semiconductor device is formed with a redistribution layer over a semiconductor die to map a first bond pad pitch on the semiconductor die to a second larger solder bump pitch for use in a flip chip package. The use of the arrangements allows smaller semiconductor dies, which are produced at lower costs, to be packaged in flip chip BGA packages.

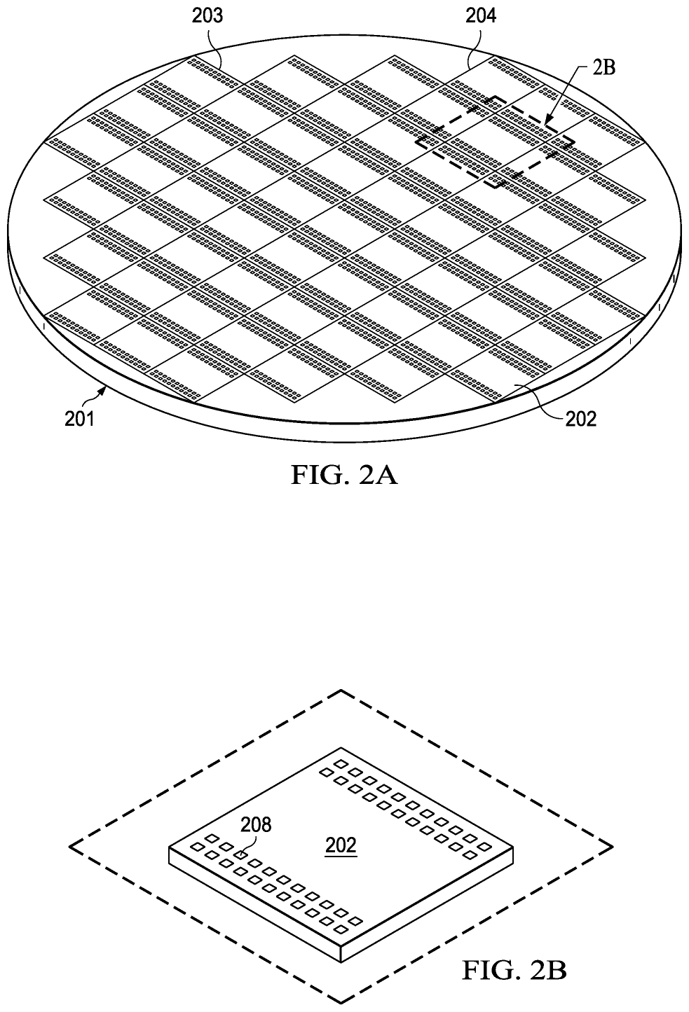

FIG. 2A illustrates in a projection view, and FIG. 2B illustrates in a close up view, a semiconductor wafer including semiconductor dies and an individual semiconductor die that are useful with the arrangements. In FIG. 2A, the semiconductor wafer 201 is shown with semiconductor dies 202 arranged in rows and columns. Scribe lanes 203 and 204 are shown between the dies and running in directions that are normal to one another, these scribe lanes provide areas for separating the completed semiconductor dies from one another by sawing, scribing or laser cutting methods. The semiconductor dies 202 each have bond pads 208 on a device side surface. FIG. 2B illustrates one semiconductor die 202 in a close up view with bond pads 208 on the device side surface. The bond pads 208 provide terminals such as input, output, and input/output pins for the semiconductor dies. IO pins of over one hundred in number, such as one hundred eighty pins, can be used. Examples of high pin count semiconductor dies include high speed data converter (HSDC) devices which may have multiple analog to digital data channels, embedded processors, which can include multiple processor cores on a single semiconductor device and which include corresponding input and output data paths, and integrated systems on chips such as systems with antennas on packages (AoP) such as radar, lidar, cellular, WiFi and other communications devices. These highly integrated semiconductor devices require many bond pad terminals and the pitch between the bond pads can be a critical design parameter for reducing device size and therefore, increasing device yield and reducing costs.

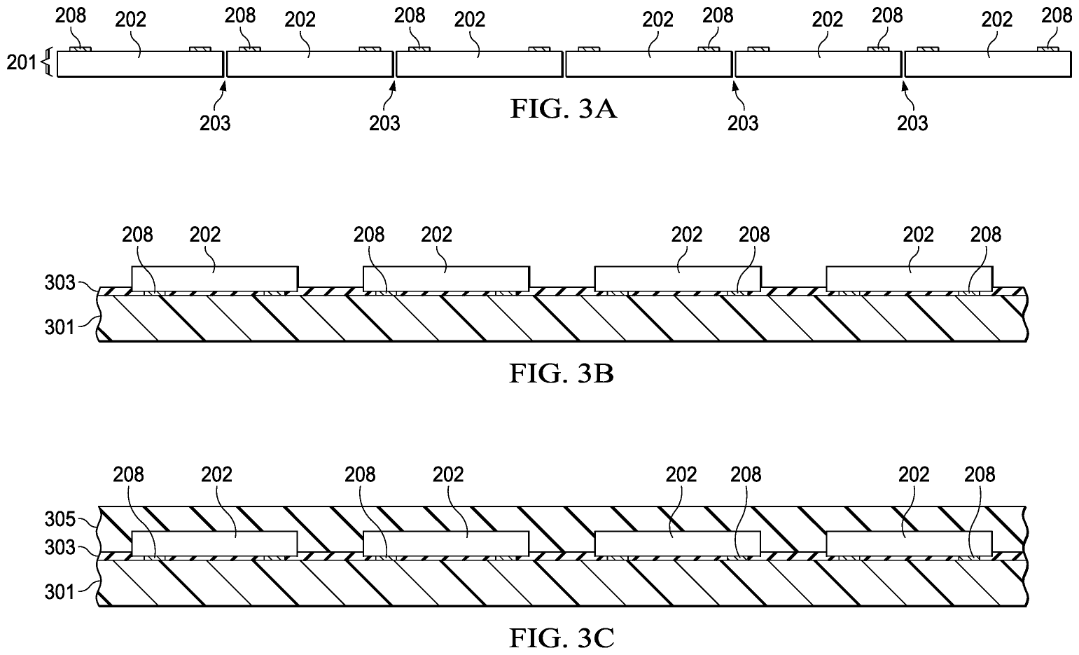

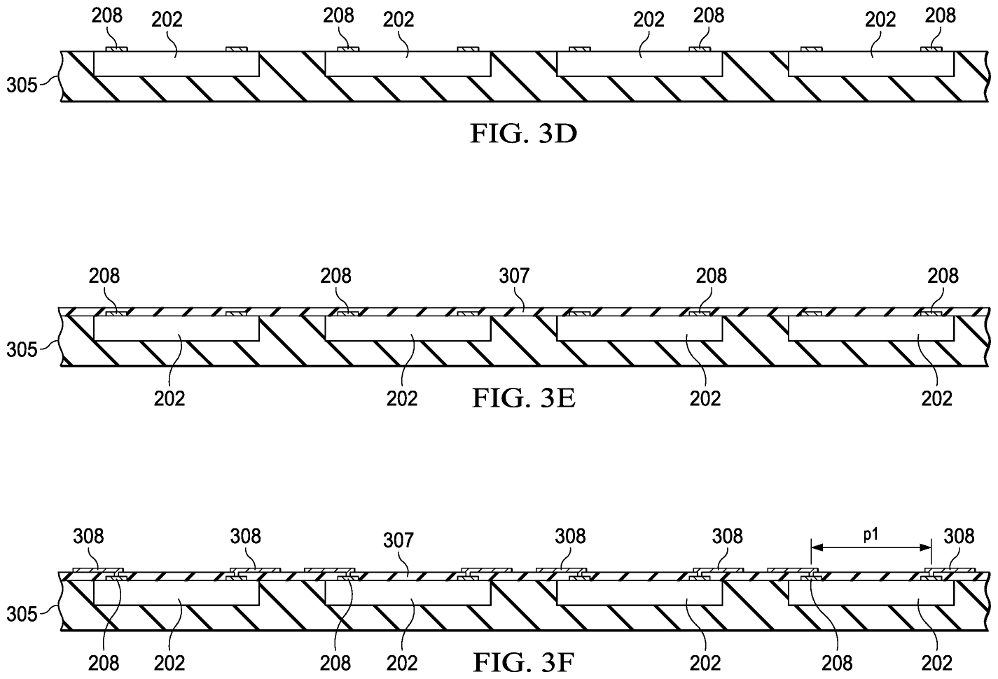

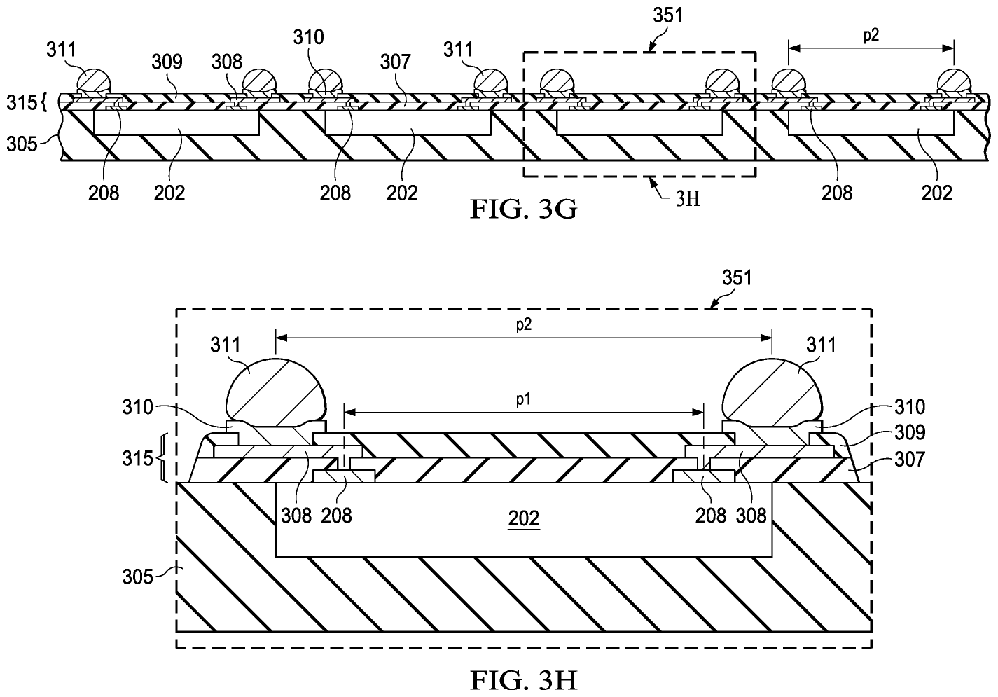

FIGS. 3A-3H illustrate, in a series of cross sectional views, selected steps for forming a completed reconstituted semiconductor device for use in an arrangement. FIG. 3A illustrates in a cross sectional view semiconductor wafer 201 with semiconductor device dies 202 arranged with bond pads 208 formed on a device side surface. The semiconductor wafer 201 can be singulated so that the semiconductor device dies 202 are separated from one another by cutting through the semiconductor wafer 201 along scribe lanes 203 between the semiconductor device dies 202, as shown in FIG. 3A.

FIG. 3B illustrates, in another cross section, the semiconductor device dies 202 after mounting to a carrier 301 by a die attach 303. The die attach 303 can be a tape, film or adhesive layer that is removable by UV or thermal energy, or which is peelable by mechanical means. The carrier 301 provides a support surface and may be a glass, semiconductor or metal substrate. The carrier 301 can be cleaned and reused for additional processing.

FIG. 3C illustrates in another cross section the semiconductor dies 202 of FIG. 3B after additional processing. In FIG. 3C, a dielectric material 305 covers the backside surface of the semiconductor dies 202, and forms a protective body. Dielectric material 305 can be, in one example, a thermoset epoxy resin mold compound. In alternative arrangements dielectric material 305 can be a thermoplastic such as acrylonitrile butadiene styrene (ABS) or acrylonitrile styrene acrylate (ASA) or other plastic. Liquid crystal polymers (LCP) can be used for dielectric 305. Epoxy, resin, or other mold compounds can be used for dielectric 305.

FIG. 3D illustrates in a cross sectional view the dielectric material 305 and the semiconductor device dies 202 after the dielectric material 305 and the semiconductor device dies 202 are removed from the carrier 301. The semiconductor device dies 202 are arranged spaced apart with bond pads 208 exposed from the dielectric material 305 for additional processing.

FIG. 3E illustrates, in another cross sectional view, the dielectric material 305 and the semiconductor device dies 202 after additional processing. In the arrangements, a passivation layer 307 is formed as a first step in forming a redistribution layer over the dielectric material 305. The redistribution layer will be used to couple the bond pads 208 to additional conductive lands that are positioned at a greater pitch that meets the requirements for a solder bumping process. The process of forming a redistribution layer begins by depositing a first passivation layer 307 over the bond pads 208 as shown in FIG. 3E. The passivation layer can be a polymer such as a polyimide.

FIG. 3F illustrates, in a further cross sectional view, the semiconductor device dies 202, the bond pads 208, and the dielectric material 305. A first trace layer 308 is formed over the passivation layer 307 in a plating operation. The first trace layer 308 is patterned to form conductors coupled to bond pads 208. The conductors can be a copper, gold, tungsten or other plated conductors. Electroplating or electroless plating can be used. The first trace layer 308 is patterned to provide conductors that expand the distance from the bond pads 208 that are at a first pitch distance p1. In an example, the first distance p1 is less than 60 microns center to center.

FIG. 3G illustrates, in another cross sectional view, the dielectric material 305 and the semiconductor dies 202 of FIG. 3F after further processing. The dielectric material 305 is covered a second passivation layer 309, and a second trace layer 310 is patterned over the second passivation layer 309. The second trace layer 310 is patterned to form conductive lands that are spaced at a distance that is larger than pitch p1 in FIG. 3F. The pitch distance between the lands in trace layer 310 is chosen to be at least large enough so that solder bumps 311 can be plated onto the second trace layer 310. In FIG. 3G, a reconstituted semiconductor device 351 is shown as one unit of a plurality of devices formed at the same time. Pitch distance between the lands in the trace layer 310 (which corresponds to a solder bump pitch distance) is greater than pitch distance p1 between bond pads on the semiconductor devices, and in an example, can be greater than 100 microns, and in another particular example, is about 150 microns, while the pitch distance p1 between bond pads can be less than 100 microns, and in some examples, less than 60 microns. Solder bumps 311 are shown formed on the conductive lands in the trace layer 310, and have the second pitch distance. Use of the arrangements with the reconstituted semiconductor device having the second pitch distance p2 between interconnects that is greater than the first pitch distance p1 between the bond pads on the semiconductor dies allows for assembly of a packaged device using solder bumps with a needed second pitch distance, while using smaller semiconductor dies, reducing the costs for the semiconductor dies and reducing costs for the assembled devices.

FIG. 3H illustrates in greater detail the feature of the reconstituted semiconductor device 351 of FIG. 3G. The semiconductor die 202 is covered by the dielectric material 305 on a back side surface and has bond pads 208 on a device side surface. Bond pads 208 are coupled to solder bumps 311 by the conductive traces 310 and conductive traces 308 in the passivation layers 309, 307 of a redistribution layer 315. The passivation layers 307, 309 lie over the dielectric material 305. The solder bumps 311 are at the second pitch distance p2, and are spaced farther apart than the bond pads 208, which are at the first pitch distance p1. By redistributing the bond pad connections from the first pitch distance on the semiconductor die to a larger pitch distance, the use of the redistribution layer 315 in the arrangements, with passivation layers 307, 309, and conductive trace layers 308, 310, enables a small die size for the semiconductor die 202 to be used in conjunction with a flip chip package with solder bumps 311.

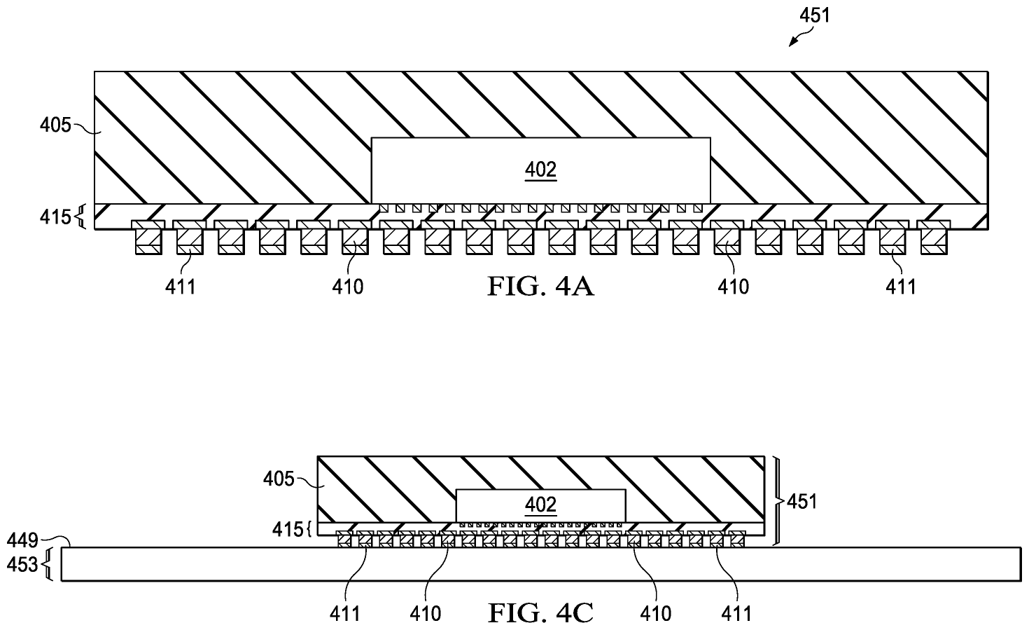

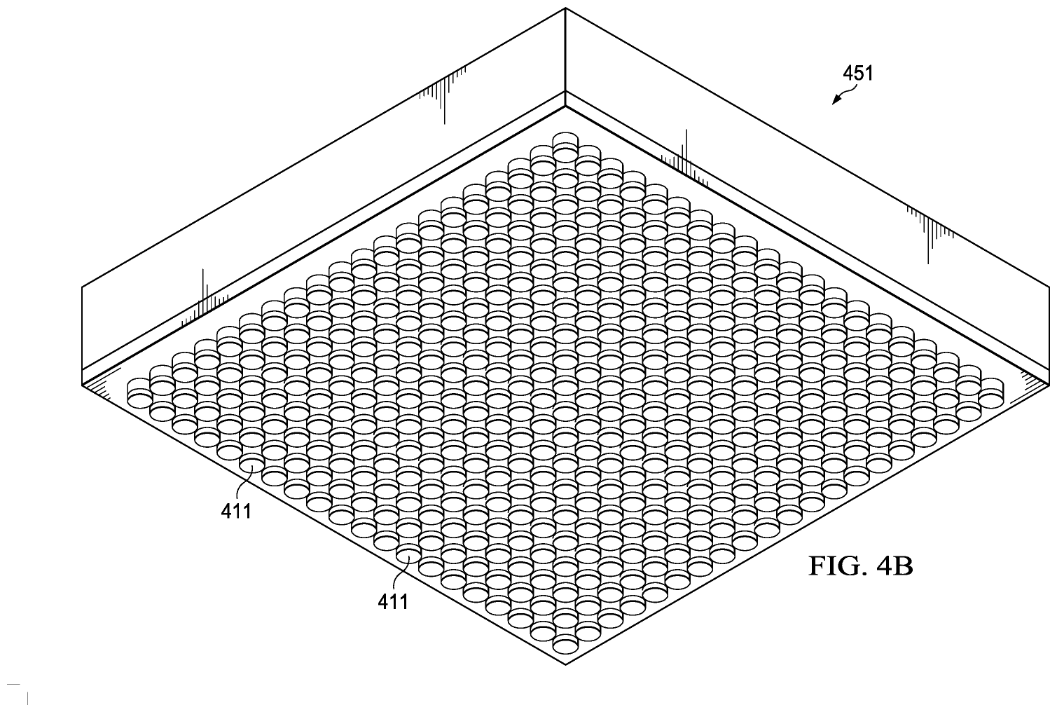

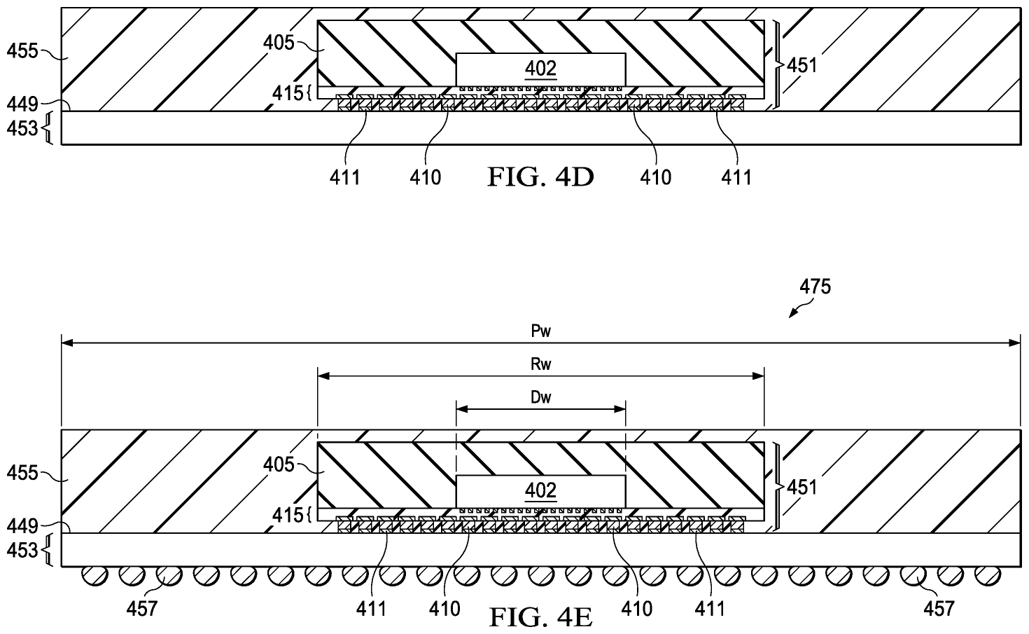

FIGS. 4A-4E illustrate, in a series of cross sections and projection views, steps for forming a packaged semiconductor device in an arrangement. FIG. 4A is a cross sectional view of a reconstituted semiconductor device 451, illustrating another example similar to reconstituted semiconductor device 351 in FIG. 3H, with a dielectric layer 405 covering the backside of a semiconductor die 402. A redistribution layer 415 includes passivation layers and conductors (not shown for clarity of illustration) with post connects 410 that include solder 411 at the distal ends of the post connects 410, the reconstituted semiconductor device 415 is configured for use in a flip chip semiconductor device package.

FIG. 4B illustrates the reconstituted semiconductor device 451 of FIG. 4A in a projection view, with the solder bumps 411 shown extending from the reconstituted semiconductor device 451. FIG. 4C illustrates the reconstituted semiconductor device 451 mounted to a device side surface 449 of a package substrate 453. The reconstituted semiconductor device 451 includes the semiconductor die 402 with the dielectric material 405 and the solder bumps 411 and is mounted to a device side surface 449 of the package substrate 453 by forming solder joints between the solder bumps 411 and the package substrate 453. The package substrate 453 can be a lead frame, a PMLF, MIS, or a multilayer package substrate which can be a ceramic package substrate, a printed circuit board substrate such as a flame retardant 4 (FR4), a BT resin substrate, or a multilayer package substrate that is built using an additive plating process, forming layers of conductors in layers of a dielectric such as a thermoplastic, resin or a mold compound. Thermoplastic materials useful in the arrangements include ABS and ASA. The package substrate 453 has conductive lands (not shown for clarity of illustration) on device side surface 449 and the reconstituted semiconductor device 451 is flip chip mounted to the conductive lands by a solder reflow process to form solder joints.

FIG. 4D illustrates in a cross sectional view the reconstituted semiconductor device 451 and the package substrate 453 with a mold compound 455 over the device side surface 449 of the 455 reconstituted semiconductor device 451. The mold compound 455 can be formed by a transfer mold process that covers the reconstituted semiconductor device 451 and a portion of the package substrate 453 with a thermoset epoxy resin mold compound. The package substrate 453 is at least partially covered by the mold compound 455. In an alternative arrangement, a protective cover or lid can be used instead of the mold compound 455 to protect the reconstituted semiconductor device 451, the lid can be sealed to the package substrate 453.

FIG. 4E illustrates in another cross sectional view a completed semiconductor device package 475 formed with BGA solder balls 457. The reconstituted semiconductor device 451 is flip chip mounted to package substrate 453, the reconstituted semiconductor device 451 is mounted to the device package substrate 453 by solder joints. The BGA solder balls 457 form the terminals of the completed packaged semiconductor device 475. The semiconductor die 402 is within the reconstituted semiconductor device 451 is flip chip mounted on the package substrate 453. BGA solder balls 457 are coupled to the reconstituted semiconductor device 451 and the semiconductor die 202 by conductive traces in the package substrate 453, and by the redistribution layer 415 in the reconstituted semiconductor device 451.

In an example, a die size for a semiconductor device to be packaged in a flip chip BGA package was reduced by use of the arrangements from a 155 micron bond pad pitch (a pitch compatible with a solder bumping process) to a 50 micron bond pad pitch. The die size required was reduced from 3.1×3.1 millimeters to 1×1 millimeter, resulting in approximately 90% reduction in silicon die cost due to the increase number of dies per wafer. While the use of the redistribution layer over the reconstituted semiconductor device dielectric material increases the costs per packaged unit, the total cost of a packaged semiconductor device was reduced by over 60 percent, so that use of the arrangements resulted in a packaged device that costs about one third of that of a packaged device made without the use of the arrangements. This result was found for several different types of semiconductor devices made on both 8 inch and 12 inch wafers using different processes. By enabling use of smaller semiconductor dies, the arrangements decrease the overall device costs even while adding elements (the materials used in forming the reconstituted semiconductor devices of the arrangements includes a dielectric material, and a redistribution layer over the dielectric material with conductors and passivation layers).

FIG. 4E illustrates some relative width dimensions. Dw is the die width, Rw is the reconstituted semiconductor device width, and Pw is the package width for the example semiconductor device package 475. In a particular example the die width (using the smaller die size enabled by use of the arrangements) was 1 millimeter, the reconstituted semiconductor device width Rw was 3 millimeters, which provides the bump pitch needed for the solder bumps on the reconstituted semiconductor device, and the package width Pw was 7 millimeters. Various die sizes and package sizes are useful with the arrangements. As semiconductor processes continue to advance, the die sizes will continue to decrease. The arrangements advantageously enable use of flip chip BGA packages with smaller die sizes and at lower overall device costs than previous approaches.

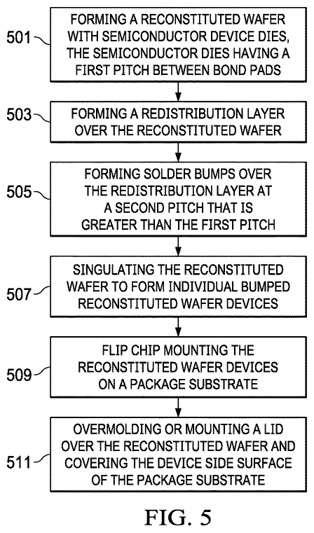

FIG. 5 illustrates, in a flow diagram, a method for forming an arrangement. At step 501, the method begins by forming a reconstituted wafer with semiconductor dies, the semiconductor dies having bond pads on a device side surface with a first pitch between the bond pads. (See FIG. 3F, pitch distance p1). At step 503, a redistribution layer is formed over the semiconductor dies on the reconstituted wafer. (See, FIGS. 3F-3G, redistribution layer 315).

At step 505, the method continues by forming solder bumps on the redistribution layer at a second pitch between the solder bumps that is greater than the first pitch. (See FIG. 3H, solder bumps 311). At step 507 the reconstituted wafer is singulated to form individual bumped reconstituted semiconductor devices (see FIG. 4A, reconstituted semiconductor device 451). At step 509 the singulated reconstituted semiconductor devices are flip chip mounted to a package substrate (see FIG. 4C, package substrate 453). At step 511, an overmolding is performed or a lid is mounted over the package substrate. (see FIG. 4D, mold compound 455). The package can be a BGA package or a QFN or other package type. For devices with many terminals a BGA or pin grid array (PGA) package can be efficiently formed using the arrangements. Other package types such as quad flat no lead (QFN) packages can be used.

Use of the processes and the arrangements allows a semiconductor die with a first minimum pitch between bond pads to be flip chip mounted to a package substrate using solder bumps at a second minimum pitch between solder bumps that is greater than the first bond pad pitch. In examples the first pitch distance is less than 100 microns, and can be less than 60 microns. The second pitch distance is greater than the first pitch distance and can be 100 microns, or 150 microns in examples. Use of the arrangements enables smaller die size for a flip chip semiconductor device package by use of a reconstituted semiconductor device with a redistribution layer to increase from a bond pad pitch of the semiconductor die to a greater pitch for the solder bumps.

Modifications are possible in the described arrangements, and other alternative arrangements are possible within the scope of the claims.

What is claimed is:

1. A method of making a semiconductor package, comprising:
forming bond pads over a device side surface of a semiconductor die, the bond pads spaced from one another at a first pitch distance that is less than 100 microns;
placing the device side surface of the semiconductor dies on a carrier;
forming a dielectric layer over a back side surface of the semiconductor dies opposite the device side surface to form a reconstituted wafer including the semiconductor dies spaced from one another;
removing the carrier from the semiconductor dies;
forming a redistribution layer over the bond pads on the device side surface of the semiconductor dies;
forming interconnects on the redistribution layer, the interconnects coupled to the bond pads by conductors in the redistribution layer, the interconnects spaced from one another by a second pitch distance that is greater than the first pitch distance;
singulating a reconstituted semiconductor device from the reconstituted wafer, the reconstituted semiconductor device comprising one of the semiconductor dies and solder bumps over the one of the semiconductor dies;
mounting the reconstituted semiconductor device onto a device side surface of a package substrate; and
covering the reconstituted semiconductor device and the device side surface of the package substrate with a protective cover.

2. The method of claim 1, wherein mounting the reconstituted semiconductor device onto a device side surface of a package substrate further comprises flip chip mounting the reconstituted semiconductor device onto a ball grid array package substrate.

3. The method of claim 1, wherein the package substrate is a ball grid array substrate, a premolded lead frame, a metal lead frame, a ceramic package substrate, or a multilayer package substrate.

4. The method of claim 1, wherein forming the redistribution layer further comprises:
forming a layer of passivation material over the bond pads of the semiconductor dies;
patterning the layer of passivation material to expose the bond pads;
plating a conductor layer on the bond pads;
forming conductive lands over the layer of passivation material configured to receive solder bumps; and
forming solder bumps on the conductive lands, the solder bumps spaced from one another by at least the second pitch distance.

5. The method of claim 1, wherein the first pitch distance is less than 60 microns.

6. The method of claim 5, wherein the second pitch distance is greater than 150 microns.

7. The method of claim 1, wherein the first pitch distance is greater than 10 microns and less than 60 microns.

8. The method of claim 7, wherein the second pitch distance is greater than 100 microns.

9. The method of claim 1, wherein forming the reconstituted wafer further comprises covering the back side surface of the semiconductor dies with one of a thermoplastic, acrylonitrile butadiene styrene (ABS), acrylonitrile styrene acrylate (ASA), resin, epoxy, plastic, or epoxy resin mold compound.

10. The method of claim 1, wherein forming the interconnects further comprises forming conductive post connects extending from proximate ends on the redistribution layer and having solder at distal ends facing away from the redistribution layer.

11. An apparatus, comprising:
a reconstituted semiconductor device that is flip chip mounted on a device side surface of a package substrate, the package substrate having terminals for connecting the package substrate to a circuit board, the reconstituted semiconductor device further comprising:
a semiconductor die mounted in a dielectric layer and having bond pads exposed from the dielectric layer, the bond pads spaced from one another by at least a first pitch distance of less than 100 microns;
a redistribution layer formed over the bond pads of the semiconductor die and having conductors in passivation layers;
solder bumps on the redistribution layer coupled to the bond pads of the semiconductor die by the conductors in the passivation layers, the solder bumps being spaced from one another by at least a second pitch distance that is greater than the first pitch distance; and
solder joints formed between the package substrate and the solder bumps, the solder joints coupling the package substrate to the semiconductor die, the bond pads on the semiconductor die coupled to terminals on the package substrate by the conductors in the redistribution layer, the solder joints, and conductors in the package substrate.

12. The apparatus of claim 11, wherein the terminal on the package substrate are solder balls for a ball grid array package.

13. The apparatus of claim 11 and further comprising a mold compound covering the reconstituted semiconductor device and the device side surface of the package substrate.

14. The apparatus of claim 11, wherein the reconstituted semiconductor device further comprises a thermoplastic, acrylonitrile butadiene styrene (ABS), acrylonitrile styrene acrylate (ASA), liquid crystal polymer, plastic, resin, epoxy, or epoxy resin mold compound covering the semiconductor die.

15. The apparatus of claim 11, wherein the package substrate is a ceramic package substrate, a lead frame, a fiberglass reinforced epoxy, a premolded lead frame, a molded interconnect substrate, a metal lead frame, or a multilayer package substrate of conductors plated in layers of passivation material.

16. The apparatus of claim 11, wherein the second distance is greater than 100 microns.

17. The apparatus of claim 11, wherein the first pitch distance is less than 60 microns, and the second pitch distance is greater than 150 microns.

18. The apparatus of claim 11, wherein the semiconductor die has a width that is less than or equal to 1 millimeter.

19. The apparatus of claim 18, wherein the reconstituted semiconductor device has a width that is at least 3 millimeters.

20. A semiconductor device package, comprising:
a reconstituted semiconductor device that is flip chip mounted on a device side surface of a package substrate of a ball grid array (BGA) package, and further comprising:
a dielectric layer covering a back side surface of a semiconductor die, and bond pads on a device side surface of the semiconductor die that are exposed from the dielectric layer, the bond pads spaced from one another by at least a first pitch distance that is less than 100 microns;
a redistribution layer formed over the bond pads of the semiconductor die and having conductors in passivation layers;
solder bumps on the redistribution layer coupled to the bond pads of the semiconductor die by the conductors in the passivation layers, the solder bumps being spaced from one another by at least a second pitch distance that is greater than the first pitch distance; and
solder joints formed between the package substrate and the solder bumps, the solder joints coupling the package substrate to the semiconductor die in the reconstituted semiconductor device, the bond pads on the semiconductor die coupled to terminals on the package substrate by the conductors in the redistribution layer, the solder joints, and conductors in the package substrate.
